(19) United States
(12) Patent Application Publication
(10) Pub. No.: US 2009/0302904 A1
(43) Pub. Date: Dec. 10, 2009

(54) Phase Frequency Detector Circuit for Implementing Low PLL Phase Noise and Low Phase Error

(75) Inventors: Darrell Lee Livezey, Auburn, CA (US); James Wilson Rae, Rochester, MN (US); Patrick Lee Rosno, Rochester, MN (US); Timothy Joseph Schmerbeck, Mantorville, MN (US)

Correspondence Address: IBM CORPORATION;ROCHESTER IP LAW DEPT 917, 3605 HIGHWAY 52 N, ROCHESTER, MN, 55901-7829, US

(73) Assignee: INTERNATIONAL BUSINESS MACHINES CORPORATION, Armonk, NY (US)

(21) Appl. No.: 12/136,218

(22) Filed: Jun. 10, 2008

(51) Int. Cl. H03L 7/06

(52) U.S. Cl. 327/156

(57) ABSTRACT

A method and Phase Frequency Detector (PFD) circuit for implementing low phase locked loop (PLL) phase noise and low phase error, and a design structure on which the subject circuit resides are provided. The PFD circuit includes a PFD latch receiving clock and reset signals, and PFD output driver circuit providing PFD output signals. The PFD latch is set by the clock and reset by the reset signal. An AND gate coupled to the PFD latch and the PFD output driver circuit includes differential inputs and outputs and applies the reset signal to the PFD latch. The PFD latch, AND gate and PFD output driver circuit are formed by current mode logic using bipolar transistors. An active loop filter generates a tuning voltage output.

### FIELD OF THE INVENTION

The present invention relates generally to the data processing field, and more particularly, relates to a method and Phase Frequency Detector circuit for implementing low phase locked loop (PLL) phase noise and low phase error, and a design structure on which the subject circuit resides.

### DESCRIPTION OF THE RELATED ART

A need exists for a phase frequency detector capable of implementing low phase locked loop (PLL) phase noise and low phase error. Such phase frequency detector must maintain functionality while running at a high frequency range.

### SUMMARY OF THE INVENTION

Principal aspects of the present invention are to provide a method and Phase Frequency Detector circuit for implementing low phase locked loop (PLL) phase noise and low phase error, and a design structure on which the subject circuit resides. Other important aspects of the present invention are to provide such method, Phase Frequency Detector circuit and design structure substantially without negative effect and that overcome many of the disadvantages of prior art arrangements.

In brief, a method and Phase Frequency Detector (PFD) circuit for implementing low phase locked loop (PLL) phase noise and low phase error, and a design structure on which the subject circuit resides are provided. The PFD circuit includes a PFD latch receiving clock and reset signals, and PFD output driver circuit providing PFD output signals. The PFD latch is set by the clock and reset by the reset signal. An AND gate coupled to the PFD latch and the PFD output driver circuit includes differential inputs and differential outputs and applies the reset signal to the PFD latch. The PFD latch, AND gate and PFD output driver circuit are formed by current mode logic using bipolar transistors.

In accordance with features of the invention, a loop filter coupled to the PFD output driver circuit includes differential inputs. The loop filter is an active filter including an operational amplifier. The loop filter enables selection of either the true or complement output of both PFD output increase and decrease signals.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is schematic and block diagram of a phase frequency detector (PFD) implemented in accordance with a method of the preferred embodiment;

FIG. 2 is a schematic diagram illustrating an AND gate of the phase frequency detector (PFD) of FIG. 1 implemented in accordance with a method of the preferred embodiment;

FIG. 3 is a schematic diagram illustrating a latch of the phase frequency detector (PFD) of FIG. 1 implemented in accordance with a method of the preferred embodiment;

FIG. 4 is a schematic diagram illustrating a PFD output driver of the phase frequency detector (PFD) of FIG. 1 implemented in accordance with a method of the preferred embodiment;

FIG. 5 is a schematic diagram illustrating a loop filter of the phase frequency detector (PFD) of FIG. 1 implemented in accordance with a method of the preferred embodiment; and

FIG. 6 is a flow diagram of a design process used in semiconductor design, manufacturing, and/or test.

### DETAILED DESCRIPTION OF THE PREFERRED EMBODIMENTS

In accordance with features of the invention, a method and Phase Frequency Detector (PFD) circuit implement low phase locked loop (PLL) phase noise and low phase error. The PFD circuit is implemented with current mode logic formed by a bipolar transistor design. The PFD circuit is a fully differential signal design providing low phase error, and eliminating the need for a conventional common mode correction circuit and noise components of the conventional common mode correction circuit.

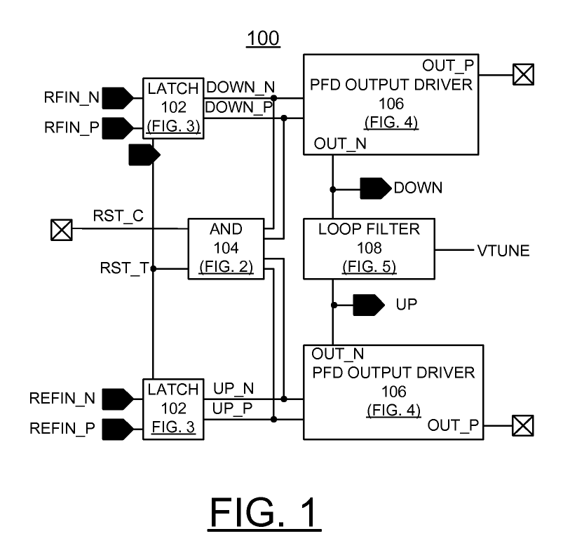

Having reference now to the drawings, in FIG. 1, there is shown a phase frequency detector (PFD) circuit generally designated by the reference character 100 in accordance with the preferred embodiment. The phase frequency detector (PFD) circuit 100 includes a PFD latch 102 receiving clock and reset signals, an AND gate 104, and PFD output driver circuit 106 providing PFD output signals. The PFD latch 102 is set by the clock and reset by the reset signal. The AND gate 104 is coupled to the PFD latch 102 and the PFD output driver circuit 106 includes differential inputs and differential outputs. The AND gate 104 applies the reset signal to the PFD latch 102. The PFD latch 102, AND gate 104 and PFD output driver circuit 106 are formed by current mode logic using bipolar transistors. An active loop filter 108 connected to the PFD output driver circuit 106 generates a tuning voltage output.

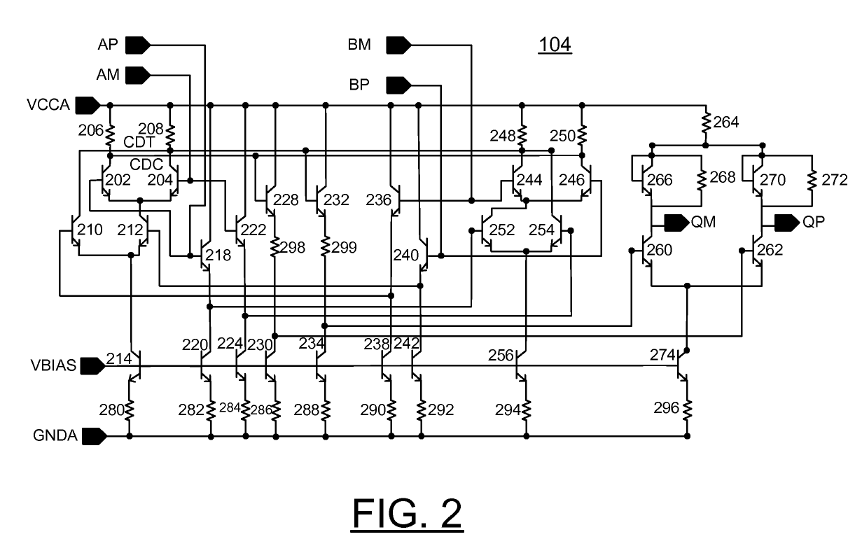

Referring now to FIG. 2, there is shown an example AND gate 104 of the phase frequency detector (PFD) 100 implemented in accordance with a method of the preferred embodiment.

The AND gate 104 is a symmetrical AND gate receiving inputs labeled AM, AP, and BM, BP from a respective input latch 102 corresponding to the latch differential outputs UP_N, UP_P, and DOWN_N, DOWN_P as shown in FIG. 1. The AND gate 104 provides differential outputs QM, QP, and applies the reset signal to the PFD latch 102 shown as RST_T, with the other output not connected as indicated in FIG. 1.

The AND gate 104 is implemented with current mode logic formed by a bipolar transistor design including NPN transistors, and is a balanced emitter coupled logic (ECL) AND gate formed with NPN transistors, as shown in FIG. 2.

The AND gate 104 includes a voltage power supply rail VCCA and a differential pair of NPN transistors 202, 204 including a respective collector connected to the voltage power supply rail VCCA by a respective one of resistors 206, 208 with input AM connected to the base of NPN transistor 204. A differential pair of NPN transistors 210, 212 includes a collector of NPN transistor 210 connected to node CDT at the connection of resistor 208 and collector of NPN transistor 204 and a collector of NPN transistor 210 connected to a common connection of respective emitter of the differential NPN transistors 202, 204. An NPN transistor 214 is connected to the common connection of respective emitter of the differential NPN transistors 210, 212.

A first transistor stack is connected to the voltage power supply rail VCCA and is formed by a series connected pair of NPN transistors 218, 220 including the input AP connected to the base of NPN transistor 218. A plurality of cross coupled transistor stacks are connected to the voltage power supply rail VCCA and are formed by a respective pair of series connected NPN transistors 222, 224; 228, 230, 232, 234; 236; 238, and 240, 242. The input BP is connected to the base of NPN transistor 240. The base of NPN transistor 228 is connected to a node CDC at the connection of resistor 206 and collector of NPN transistor 202. The base of NPN transistor 232 is connected to the node CDT at the connection of resistor 208 and collector of NPN transistor 204.

A differential pair of NPN transistors 244, 246 includes a respective collector connected to the voltage power supply rail VCCA by a respective one of resistors 248, 250 with input BM connected to the base of NPN transistor 204. A differential pair of NPN transistors 252, 254 includes a collector of NPN transistor 254 connected to node CDT at the connection of resistor 248 and a collector of NPN transistor 244 and a collector of NPN transistor 252 connected to the common connection of respective emitter of the differential NPN transistors 244, 246. An NPN transistor 256 is connected to the common connection of respective emitter of the differential NPN transistors 252, 254.

A differential pair of NPN transistors 260, 262 includes a respective collector connected to the voltage power supply rail VCCA by a resistor 264 and a respective parallel connected NPN transistor 266 and a resistor 268; and NPN transistor 270 and a resistor 272. An NPN transistor 274 is connected to the common connection of respective emitter of the differential NPN transistors 262, 264.

A voltage bias input VBIAS is applied to the base of each of the NPN transistors 214, 220, 224, 230, 234, 238, 242, 256, and 274. The emitter of the respective NPN transistors 214, 220, 224, 230, 234, 238, 242, 256, and 274 is connected by a respective resistor 280, 282, 284, 286, 288, 290, 292, 294, and 296 to ground potential. The common emitter and collector connection of NPN transistors 222, 224 is connected to the base of differential NPN transistor 252. The emitter and collector connection of NPN transistors 228, 230 are connected by a resistor 298 and the connection of resistor 298 and NPN transistor 230 is connected to the base of differential NPN transistor 262. The emitter and collector connection of NPN transistors 232, 234 are connected by a resistor 299 and the connection of resistor 299 and NPN transistor 234 is connected to the base of differential NPN transistor 260. The common emitter and collector connection of NPN transistors 236; 238 is connected to the base of differential NPN transistor 210. The common emitter and collector connection of NPN transistors 240, 242 is connected to the base of differential NPN transistor 212.

The differential outputs QM, QP of AND gate 104 are provided at the collector of respective differential NPN transistors 262, 264. The AND gate 104 effectively provides a low phase error design with the balanced emitter coupled logic AND gate via cross coupled transistor stacks and with appropriate level shifted and swing reset outputs.

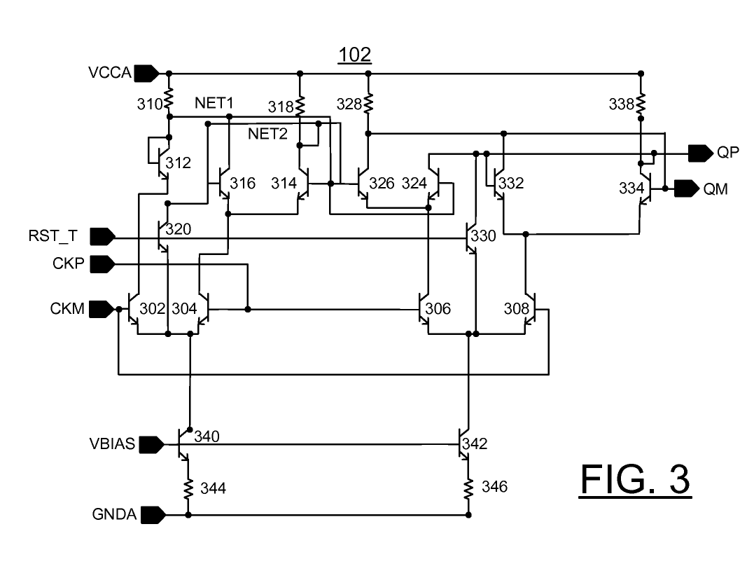

Referring now to FIG. 3, there is shown an example latch 102 of the phase frequency detector (PFD) 100 implemented in accordance with a method of the preferred embodiment. PFD latch 102 includes a pair of symmetrical latches 102 respectively providing PFD latch differential outputs UP_N, UP_P, and DOWN_N, DOWN_P as shown in FIG. 1.

PFD latch 102 is implemented with current mode logic formed by a bipolar transistor design including NPN transistors, and is a balanced emitter coupled logic (ECL) formed with NPN transistors, as shown in FIG. 3. PFD latch 102 includes a master latch on the left side and a slave latch on the left side as shown in FIG. 3.

PFD latch 102 receives the reset input RST_T and the differential clock inputs CKP, CKM corresponding to the respective ones of differential clock inputs RFIN_N, RFIN_P, and REFIN_N, REFIN_P as shown in FIG. 1. PFD latch 102 provides differential PFD outputs QM, QP corresponding to the respective ones of the latch differential outputs UP_N, UP_P, and DOWN_N, DOWN_P as shown in FIG. 1.

PFD latch 102 includes the voltage power supply rail VCCA and a first differential pair of NPN transistors 302, 304 and a second differential pair of NPN transistors 306, 308 with the differential clock input CKM applied to a base of NPN transistors 302, 306 and the differential clock input CKP applied to a base of NPN transistors 304, 308. The collector of NPN transistor 302 is connected to the voltage power supply rail VCCA by a series connected resistor 310 and a diode connected NPN transistor 312.

A pair of NPN transistors 314, 316 includes a common emitter connected to the gate of differential pair NPN transistor 304. A collector of NPN transistor 314 is connected to the voltage power supply rail VCCA by a resistor 318. The connection of the resistor 310 and collector of NPN transistor 312 at a node NET1 is connected to the collector of NPN transistor 316.

The connection of the resistor 318 and the collector of NPN transistor 314 at a node NET2 is connected to the collector of an NPN transistor 320 with an emitter connected to the common emitter connection of the first differential pair of NPN transistors 302, 304. The reset input RST_T is applied to the base of NPN transistor 320.

A pair of NPN transistors 324, 326 includes a common emitter connected to the gate of differential pair NPN transistor 306. A collector of NPN transistor 326 connected to the voltage power supply rail VCCA by a resistor 328. The base of NPN 324 is connected to the collector of NPN transistor 316 at the node NET1. The base of NPN 326 is connected to the collector of NPN transistor 314 at the node NET2. The connection of the resistor 318 and the collector of NPN transistor 314 is the differential output at differential output node QM.

A pair of NPN transistors 332, 334 includes a common emitter connected to the gate of differential pair NPN transistor 308. A collector of NPN transistor 334 is connected to the voltage power supply rail VCCA by a resistor 338. The connection of the resistor 338 and collector of NPN transistor 334 at a differential output node QP is connected to the base of NPN transistor 332. The collector of the NPN transistor 332 is connected to the collector of NPN transistor 314 at the differential output node QM.

The connection of the resistor 338 and the collector of NPN transistor 334 at the differential output node QP is connected to the collector of an NPN transistor 320 with an emitter connected to the common emitter connection of the first differential pair of NPN transistors 302, 304. The reset input RST_T is applied to the base of NPN transistors 330.

A pair of current source NPN transistors 340, 342 includes a respective collector connected to respective common emitter connection of the first differential pair of NPN transistors 302, 304 and the second differential pair of NPN transistors 306, 308. A voltage bias input VBIAS is applied to the base of each of the NPN transistors 340, 342. The emitter of each of the NPN transistors 340, 342 is connected by a respective resistor 344, 346 to ground potential.

The latch 102 is set by the clock signal CKP, CKM where P indicates high and M indicates low. When clock signal is low, value is read into the differential outputs QP and QM, where the clock sets high and is reset by the reset pulse RST_T.

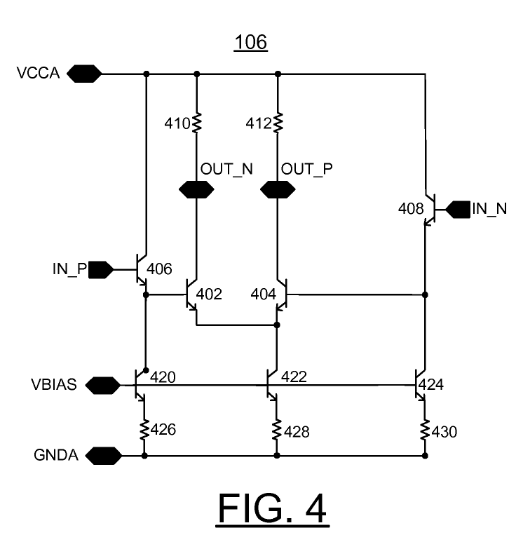

Referring now to FIG. 4, there is shown an example PFD output driver 106 of the phase frequency detector (PFD) 100 implemented in accordance with a method of the preferred embodiment. The PFD output driver 106 is implemented with current mode logic formed by a bipolar transistor design including NPN transistors. The PFD output driver 106 includes a balanced pair of output drivers receiving inputs labeled IN_N, IN_P from a respective input latch 102 corresponding to the respective latch differential outputs UP_N, UP_P, and DOWN_N, DOWN_P as shown in FIG. 1. The PFD output driver 106 provides differential outputs OUT_N, OUT_P, as shown in FIG. 4.

The PFD output driver 106 includes the voltage power supply rail VCCA and a differential pair of NPN transistors 402, 404 having a common emitter connection. The differential input IN_P is applied to a base of an NPN transistor 406 and the differential input IN_N is applied to a base of NPN transistors 408. The collector of the respective NPN transistors 402, 404 is connected to the voltage power supply rail VCCA by a respective pull-up resistor 410, 412. The respective connection of the pull-up resistor 410 and collector of NPN transistor 402 and of the pull-up resistor 412 and collector of NPN transistor 404 provides the differential outputs OUT_N, OUT_P of the output driver 106. The base of the NPN transistor 402 is connected to emitter of NPN transistor 406. The base of the NPN transistor 404 is connected to emitter of NPN transistor 408. A voltage bias input VBIAS is applied to the base of each of the NPN transistors 420, 422, 424.

The PFD output driver 106 includes multiple current sources defined by a plurality of current source NPN transistors 420, 422, 424 and connected by a respective resistor 426, 428, 430 to ground potential. The collector of NPN transistor 422 is connected to the emitter of NPN transistor 406. The collector of NPN transistor 422 is connected to the common emitter connection of the differential pair of NPN transistors 402, 404. The collector of NPN transistor 424 is connected to the emitter of NPN transistor 408. The output current and pull-up resistance of the PFD output driver 106 is matched to the impedance of the active loop filter 108.

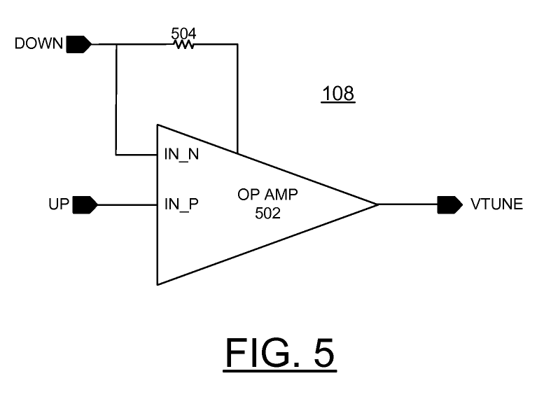

Referring now to FIG. 5, there is shown an example an example loop filter 108 of the phase frequency detector (PFD) 100 implemented in accordance with a method of the preferred embodiment. The loop filter 108 is coupled to the PFD output driver circuit 106 receiving differential outputs UP, DOWN applied to respective differential inputs IN_P, IN_N. The loop filter 108 is an active filter defined by an operational amplifier 502 with an input impedance 504. The loop filter 108 is a conventional low noise operational amplifier 502, including for example, an N-channel field effect transistor (NFET) differential pair input that enables selection of either the true or complement output of both PFD output increase and decrease signals.

In accordance with features of the invention, active currents into the loop filter 108 are avoided as much as possible because these lead to the inevitable increase in 1/f and shot noise. The selection of the complement output allows both PFD output increase UP and decrease DOWN signals to remain at approximately the voltage supply level most of the time receiving a current pulse when correction pulses are made. As a result, the output of the PFD 100 generally includes only resistor thermal noise most of the time minimizing 1/f or shot noise components. During a correction pulse only the 1/f noise of the bipolar current is seen providing substantial improvement over conventional CMOS digital switching noise. Also as a result of the PFD outputs remaining approximately at the voltage supply level, the overall phase error of the PFD 100 remains low independent of the loop filter voltage level at the output of the operational amplifier 502.

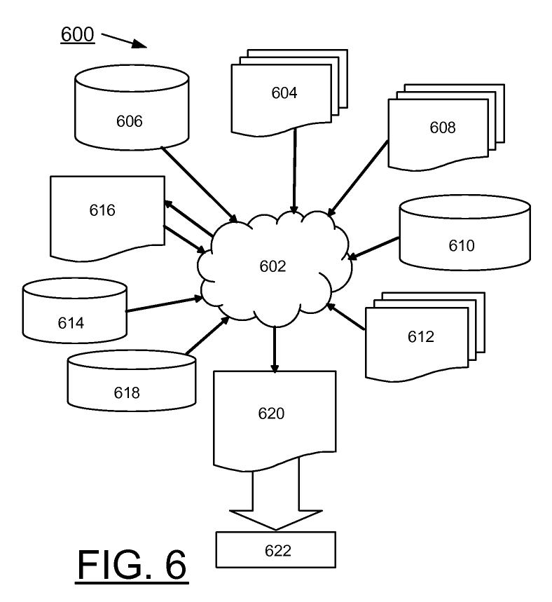

FIG. 6 shows a block diagram of an example design flow 600. Design flow 600 may vary depending on the type of IC being designed. For example, a design flow 600 for building an application specific IC (ASIC) may differ from a design flow 600 for designing a standard component. Design structure 602 is preferably an input to a design process 604 and may come from an IP provider, a core developer, or other design company or may be generated by the operator of the design flow, or from other sources. Design structure 602 comprises circuit 100 in the form of schematics or HDL, a hardware-description language, for example, Verilog, VHDL, C, and the like. Design structure 602 may be contained on one or more machine readable medium. For example, design structure 602 may be a text file or a graphical representation of circuit 100. Design process 604 preferably synthesizes, or translates, circuit 100 into a netlist 606, where netlist 606 is, for example, a list of wires, transistors, logic gates, control circuits, I/O, models, etc. that describes the connections to other elements and circuits in an integrated circuit design and recorded on at least one of machine readable medium. This may be an iterative process in which netlist 606 is resynthesized one or more times depending on design specifications and parameters for the circuit.

Design process 604 may include using a variety of inputs; for example, inputs from library elements 608 which may house a set of commonly used elements, circuits, and devices, including models, layouts, and symbolic representations, for a given manufacturing technology, such as different technology nodes, 32 nm, 45 nm, 90 nm, and the like, design specifications 610, characterization data 612, verification data 614, design rules 616, and test data files 618, which may include test patterns and other testing information. Design process 604 may further include, for example, standard circuit design processes such as timing analysis, verification, design rule checking, place and route operations, and the like. One of ordinary skill in the art of integrated circuit design can appreciate the extent of possible electronic design automation tools and applications used in design process 604 without deviating from the scope and spirit of the invention. The design structure of the invention is not limited to any specific design flow.

Design process 604 preferably translates an embodiment of the invention as shown in FIGS. 1, 2, 3, 4, and 5 along with any additional integrated circuit design or data (if applicable), into a second design structure 620. Design structure 620 resides on a storage medium in a data format used for the exchange of layout data of integrated circuits, for example, information stored in a GDSII (GDS2), GL1, OASIS, or any other suitable format for storing such design structures. Design structure 620 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 1, 2, 3, 4, and 5. Design structure 620 may then proceed to a stage 622 where, for example, design structure 620 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A Phase Frequency Detector (PFD) circuit for implementing low phase locked loop (PLL) phase noise and low phase error comprising:
a PFD latch receiving a differential clock signal and a reset signal, said PFD latch being set by the differential clock signal and reset by the reset signal and providing differential output signals;
an PFD output driver circuit coupled to said PFD latch, said PFD output driver circuit receiving said PFD latch differential output signals and providing differential PFD output signals;
an AND gate coupled to the PFD latch and the PFD output driver circuit applying the reset signal to said PFD latch; said AND gate including differential inputs and differential outputs; and
said PFD latch, said AND gate and said PFD output driver circuit formed by current mode logic using bipolar transistors.

2. The Phase Frequency Detector (PFD) circuit as recited in claim 1 further includes a loop filter coupled to the PFD output driver circuit; said loop filter including differential inputs.

3. The Phase Frequency Detector (PFD) circuit as recited in claim 2 wherein said loop filter is an active filter including an operational amplifier.

4. The Phase Frequency Detector (PFD) circuit as recited in claim 2 wherein said PFD output driver circuit providing differential PFD output signals of both PFD output increase and decrease signals and wherein said loop filter enables selection of either a true or complement output of said differential PFD output signals of both PFD output increase and decrease signals.

5. The Phase Frequency Detector (PFD) circuit as recited in claim 1 wherein said PFD latch includes a balanced pair of latches, each receiving a differential clock signal and the reset signal and providing said differential output signals of respectively differential output increase signals and differential output decrease signals.

6. The Phase Frequency Detector (PFD) circuit as recited in claim 1 wherein said AND gate is a balanced emitter coupled logic (ECL) AND gate.

7. The Phase Frequency Detector (PFD) circuit as recited in claim s wherein said PFD output driver circuit includes a predefined output current and output pull-up resistance for an impedance of said loop filter.

8. The Phase Frequency Detector (PFD) circuit as recited in claim 1 wherein said PFD output driver circuit includes a balanced pair of output drivers respectively providing differential output increase signals and differential output decrease signals.

9. The Phase Frequency Detector (PFD) circuit as recited in claim 1 wherein said PFD output driver circuit includes a differential NPN transistor pair receiving said PDF latch differential output signals and a respective pull-up resistor connected between a voltage power supply and respective collector of said differential NPN transistor pair and a current source connected between a common connection of respective emitter of said differential NPN transistor pair and ground potential.

10. A method for implementing low phase locked loop (PLL) phase noise and low phase error with a Phase Frequency Detector (PFD) circuit comprising:
providing a PFD latch receiving a differential clock signal and a reset signal, said PFD latch being set by the differential clock signal and reset by the reset signal and providing differential output signals;
connecting an PFD output driver circuit to said PFD latch, said PFD output driver circuit receiving said PFD latch differential output signals and providing differential PFD output signals;
connecting an AND gate to the PFD latch and the PFD output driver circuit, said AND gate including differential inputs and differential outputs;
applying the reset signal to said PFD latch with said AND gate; and
forming said PFD latch, said AND gate and said PFD output driver circuit by current mode logic using bipolar transistors.

11. The method for implementing low phase locked loop (PLL) phase noise and low phase error as recited in claim 10 further includes connecting a loop filter to the PFD output driver circuit; said loop filter including differential inputs.

12. The method for implementing low phase locked loop (PLL) phase noise and low phase error as recited in claim 10 further includes connecting an active loop filter including an operational amplifier to the PFD output driver circuit; matching a pull-up resistance of said PFD output driver circuit to an impedance of said active loop filter.

13. The method for implementing low phase locked loop (PLL) phase noise and low phase error as recited in claim 10 wherein forming said PFD latch, said AND gate and said PFD output driver circuit by current mode logic using bipolar transistors includes using emitter coupled logic (ECL).

14. A design structure embodied in a machine readable medium used in a design process, the design structure comprising:
a Phase Frequency Detector (PFD) latch receiving a differential clock signal and a reset signal, said PFD latch being set by the differential clock signal and reset by the reset signal and providing differential output signals;
an PFD output driver circuit coupled to said PFD latch, said PFD output driver circuit receiving said PFD latch differential output signals and providing differential PFD output signals;
an AND gate coupled to the PFD latch and the PFD output driver circuit applying the reset signal to said PFD latch; said AND gate including differential inputs and differential outputs; and
said PFD latch, said AND gate and said PFD output driver circuit formed by current mode logic using bipolar transistors.

15. The design structure of claim 14, wherein the design structure comprises a netlist, which describes the circuit.

16. The design structure of claim 14, wherein the design structure resides on storage medium as a data format used for the exchange of layout data of integrated circuits.

17. The design structure of claim 14, wherein the design structure includes at least one of test data files, characterization data, verification data, or design specifications.
